(19) United States
(12) Patent Application Publication
(10) Pub. No.: US 2024/0319343 A1
(43) Pub. Date: Sep. 26, 2024

(54) SYSTEMS AND TECHNIQUES FOR MITIGATING CROSSTALK AND INTERFERENCE FOR FLASH IMAGING LIGHT DETECTION AND RANGING (LiDAR) DEVICES

(71) Applicant: GM Cruise Holdings LLC, San Francisco, CA (US)

(72) Inventor: Jan Jaakkola, San Jose, CA (US)

(21) Appl. No.: 18/186,721

(22) Filed: Mar. 20, 2023

(51) Int. Cl. G01S 7/4863; G01S 17/42; G02B 6/35; H01L 31/107; H01S 5/183

(52) U.S. Cl. CPC G01S 7/4863; G01S 17/42; G02B 6/3518; H01L 31/107; H01S 5/18361

(57) ABSTRACT

Systems and techniques are provided for mitigating crosstalk and interference for flash LiDAR sensors. An example method includes transmitting, via at least one laser, a first laser beam that is directed through at least one diffractive optical element configured to generate a first transmitted beamlet group and a second transmitted beamlet group; receiving, via a first portion of a plurality of light sensors, a first set of reflected light signals corresponding to the first transmitted beamlet group; receiving, via a second portion of the plurality of light sensors, a second set of reflected light signals corresponding to the second transmitted beamlet group; and determining a distance between the LiDAR apparatus and at least one object based on at least one of the first set of reflected light signals and the second set of reflected light signals.

### BACKGROUND

### 1. Technical Field

The present disclosure generally relates to autonomous vehicles and, more specifically, to systems and techniques for mitigating crosstalk and interference for flash imaging Light Detection and Ranging (LiDAR) sensors that may be used by autonomous vehicles.

### 2. Introduction

Sensors are commonly integrated into a wide array of systems and electronic devices such as, for example, camera systems, mobile phones, autonomous systems (e.g., autonomous vehicles, unmanned aerial vehicles or drones, autonomous robots, etc.), computers, smart wearables, and many other devices. The sensors allow users to obtain sensor data that measures, describes, and/or depicts one or more aspects of a target such as an object, a scene, a person, and/or any other targets. For example, an image sensor can be used to capture frames (e.g., video frames and/or still pictures/images) depicting a target(s) from any electronic device equipped with an image sensor. As another example, a light detection and ranging (LiDAR) sensor can be used to determine ranges (variable distance) of one or more targets by directing a laser to a surface of an entity (e.g., a person, an object, a structure, an animal, etc.) and measuring the time for light reflected from the surface to return to the LiDAR.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1 is a diagram illustrating an example system environment that can be used to facilitate autonomous vehicle (AV) navigation and routing operations, according to some aspects of the present disclosure;

FIG. 2 is a diagram illustrating an example system that includes a flash imaging LiDAR, according to some aspects of the present disclosure;

FIG. 3 is a diagram illustrating an example of a flash imaging LiDAR, according to some aspects of the present disclosure;

FIG. 4 is a diagram illustrating another example of a flash imaging LiDAR, according to some aspects of the present disclosure;

FIG. 5 is a diagram illustrating another example of a flash imaging LiDAR, according to some aspects of the present disclosure;

FIG. 6 is a diagram illustrating another example of a flash imaging LiDAR, according to some aspects of the present disclosure;

FIG. 7A is a diagram illustrating an example system that includes a flash imaging LiDAR, according to some aspects of the present disclosure;

FIG. 7B is a set of intensity plots associated with a flash imaging LiDAR, according to some aspects of the present disclosure;

FIG. 8A is a diagram illustrating another example system that includes a flash imaging LiDAR, according to some aspects of the present disclosure;

FIG. 8B is another set of intensity plots associated with a flash imaging LiDAR, according to some aspects of the present disclosure;

FIG. 9 is a flow chart illustrating an example process for operating a flash imaging LiDAR, according to some examples of the present disclosure; and

FIG. 10 is a diagram illustrating an example system architecture for implementing certain aspects described herein, according to some examples of the present disclosure.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

Generally, sensors are integrated into a wide array of systems and electronic devices such as, for example, camera systems, mobile phones, autonomous systems (e.g., autonomous vehicles, unmanned aerial vehicles or drones, autonomous robots, etc.), computers, smart wearables, and many other devices. The sensors allow users to obtain sensor data that measures, describes, and/or depicts one or more aspects of a target such as an object, a scene, a person, and/or any other targets. For example, an image sensor can be used to capture frames (e.g., video frames and/or still pictures/images) depicting a target(s) from any electronic device equipped with an image sensor. As another example, a light detection and ranging (LiDAR) sensor can be used to determine ranges (variable distance) of one or more targets by directing a laser to a surface of an entity (e.g., a person, an object, a structure, an animal, etc.) and measuring the time of flight (e.g., time to receive reflection corresponding to LiDAR transmission).

In a flash imaging LiDAR system, a light source (e.g., wide diverging laser) illuminates the entire field of view in a single pulse and light sensor (e.g., pixels) collects the reflected light from all of the directions within the field of view. In some cases, flash imaging LiDARs may be susceptible to blooming, which can occur when the charge in a pixel exceeds the saturation level, and the charge starts to fill adjacent pixels. In some examples, blooming may be caused by factors such as optical crosstalk, electrical crosstalk, stray light, flash illumination, etc. In some cases, blooming may be somewhat mitigated by improving the optical design of the lens elements in the LiDAR and/or by using digital signal processing (DSP) techniques. However, such approaches fail to adequately resolve the effects of blooming because optical signals are being received by incorrect detector pixels.

Systems, apparatuses, processes (also referred to as methods), and computer-readable media (collectively referred to as “systems and techniques”) are described herein for mitigating interference and crosstalk (e.g., blooming) in flash imaging LiDAR systems. In some aspects, a flash imaging LiDAR can be configured to create an illumination pattern that is based on tightly collimated beamlets (e.g., beamlet groups) rather than a single diffuse flash. In some cases, the beamlet groups may be created by using a diffractive optical element. In some examples, the beamlet groups may be created by using a vertical-cavity surface-emitting laser (VCSEL) array. In some aspects, the VCSEL array may be electronically addressable (e.g., individual elements of the array may be enabled/disabled). In some aspects, spreading out of the beamlets or the beamlet groups can reduce optical crosstalk because there will be less undesired optical power in the vicinity of the pixels.

In some configurations, the beamlet groups can be generated using different lasers. In some cases, the beamlet groups can be interlaced. In some examples, the beamlet groups may be steered by using a beamlet steering device. Examples of beamlet steering devices can include optomechanical devices such as Risley prisms, MEMS mirrors, and tuning forks. Further examples of beamlet steering devices can include optoelectrical devices such as meta surfaces that may be based on liquid crystal technologies. In some aspects, spreading out of the beamlets or the beamlet groups can reduce optical crosstalk because there will be less undesired optical power in the vicinity of the pixels.

In some aspects, different laser sources can be used to transmit beamlet groups at different times. In some examples, the pulse interval between consecutive transmissions by a laser source and/or between transmission from different laser sources can be varied to reduce potential crosstalk as pulses are accumulated by the receiver of the LiDAR. In some instances, pulse intervals may be fixed, random, pseudorandom, or sequenced (e.g., to minimize probability of simultaneous pulses). In some examples, pulse intervals may be controlled but variable and/or pseudorandom. In some cases, multiple pulses may be in the air at the same time. That is, a second pulse can be transmitted before any or all of the reflections from an earlier pulse have been received. In some configurations, the transmit power of the laser and/or the receiver gain of the light sensors can be adjusted to further mitigate crosstalk and interference.

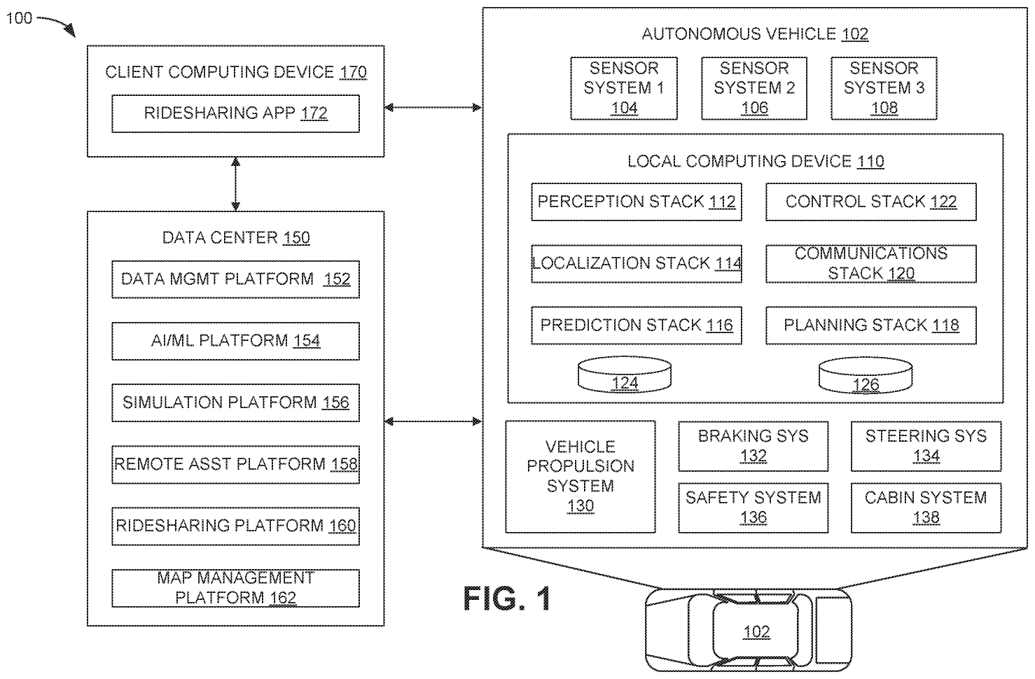

FIG. 1 is a diagram illustrating an example autonomous vehicle (AV) environment system 100, according to some examples of the present disclosure. One of ordinary skill in the art will understand that, for the AV environment system 100 and any system discussed in the present disclosure, there can be additional or fewer components in similar or alternative configurations. The illustrations and examples provided in the present disclosure are for conciseness and clarity. Other examples may include different numbers and/or types of elements, but one of ordinary skill the art will appreciate that such variations do not depart from the scope of the present disclosure.

In this example, the AV environment system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, other Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

The AV 102 can navigate roadways without a human driver based on sensor signals generated by sensor systems 104, 106, and 108. The sensor systems 104-108 can include one or more types of sensors and can be arranged about the AV 102. For instance, the sensor systems 104-108 can include Inertial Measurement Units (IMUs), cameras (e.g., still image cameras, video cameras, etc.), light sensors (e.g., LiDAR systems, ambient light sensors, infrared sensors, etc.), RADAR systems, GPS receivers, audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LiDAR system, and the sensor system 108 can be a RADAR system. Other examples may include any other number and type of sensors.

The AV 102 can also include several mechanical systems that can be used to maneuver or operate the AV 102. For instance, the mechanical systems can include a vehicle propulsion system 130, a braking system 132, a steering system 134, a safety system 136, and a cabin system 138, among other systems. The vehicle propulsion system 130 can include an electric motor, an internal combustion engine, or both. The braking system 132 can include an engine brake, brake pads, actuators, and/or any other suitable componentry configured to assist in decelerating the AV 102. The steering system 134 can include suitable componentry configured to control the direction of movement of the AV 102 during navigation. The safety system 136 can include lights and signal indicators, a parking brake, airbags, and so forth. The cabin system 138 can include cabin temperature control systems, in-cabin entertainment systems, and so forth. In some examples, the AV 102 might not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

The AV 102 can include a local computing device 110 that is in communication with the sensor systems 104-108, the mechanical systems 130-138, the data center 150, and/or the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a prediction stack 116, a planning stack 118, a communications stack 120, a control stack 122, an AV operational database 124, and an HD geospatial database 126, among other stacks and systems.

The perception stack 112 can enable the AV 102 to “see” (e.g., via cameras, LiDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 126, other components of the AV, and/or other data sources (e.g., the data center 150, the client computing device 170, third party data sources, etc.). The perception stack 112 can detect and classify objects and determine their current locations, speeds, directions, and the like. In addition, the perception stack 112 can determine the free space around the AV 102 (e.g., to maintain a safe distance from other objects, change lanes, park the AV, etc.). The perception stack 112 can identify environmental uncertainties, such as where to look for moving objects, flag areas that may be obscured or blocked from view, and so forth. In some examples, an output of the prediction stack can be a bounding area around a perceived object that can be associated with a semantic label that identifies the type of object that is within the bounding area, the kinematic of the object (information about its movement), a tracked path of the object, and a description of the pose of the object (its orientation or heading, etc.).

The mapping and localization stack 114 can determine the AV's position and orientation (pose) using different methods from multiple systems (e.g., GPS, IMUs, cameras, LiDAR, RADAR, ultrasonic sensors, the HD geospatial database 126, etc.). For example, in some cases, the AV 102 can compare sensor data captured in real-time by the sensor systems 104-108 to data in the HD geospatial database 126 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LiDAR). If the mapping and localization information from one system is unavailable, the AV 102 can use mapping and localization information from a redundant system and/or from remote data sources.

The prediction stack 116 can receive information from the localization stack 114 and objects identified by the perception stack 112 and predict a future path for the objects. In some examples, the prediction stack 116 can output several likely paths that an object is predicted to take along with a probability associated with each path. For each predicted path, the prediction stack 116 can also output a range of points along the path corresponding to a predicted location of the object along the path at future time intervals along with an expected error value for each of the points that indicates a probabilistic deviation from that point.

The planning stack 118 can determine how to maneuver or operate the AV 102 safely and efficiently in its environment. For example, the planning stack 118 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., emergency vehicle blaring a siren, intersections, occluded areas, street closures for construction or street repairs, double-parked cars, etc.), traffic rules and other safety standards or practices for the road, user input, and other relevant data for directing the AV 102 from one point to another and outputs from the perception stack 112, localization stack 114, and prediction stack 116. The planning stack 118 can determine multiple sets of one or more mechanical operations that the AV 102 can perform (e.g., go straight at a specified rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 118 can select from multiple backup plans to carry out. For example, while preparing to change lanes to turn right at an intersection, another vehicle may aggressively cut into the destination lane, making the lane change unsafe. The planning stack 118 could have already determined an alternative plan for such an event. Upon its occurrence, it could help direct the AV 102 to go around the block instead of blocking a current lane while waiting for an opening to change lanes.

The control stack 122 can manage the operation of the vehicle propulsion system 130, the braking system 132, the steering system 134, the safety system 136, and the cabin system 138. The control stack 122 can receive sensor signals from the sensor systems 104-108 as well as communicate with other stacks or components of the local computing device 110 or a remote system (e.g., the data center 150) to effectuate operation of the AV 102. For example, the control stack 122 can implement the final path or actions from the multiple paths or actions provided by the planning stack 118. This can involve turning the routes and decisions from the planning stack 118 into commands for the actuators that control the AV's steering, throttle, brake, and drive unit.

The communications stack 120 can transmit and receive signals between the various stacks and other components of the AV 102 and between the AV 102, the data center 150, the client computing device 170, and other remote systems. The communications stack 120 can enable the local computing device 110 to exchange information remotely over a network, such as through an antenna array or interface that can provide a metropolitan WIFI network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communications stack 120 can also facilitate the local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 126 can store HD maps and related data of the streets upon which the AV 102 travels. In some examples, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane centerline, lane boundaries, type of lane boundaries, etc.) and related attributes (e.g., direction of travel, speed limit, lane type, etc.). The lanes and boundaries layer can also include three-dimensional (3D) attributes related to lanes (e.g., slope, elevation, curvature, etc.). The intersections layer can include geospatial information of intersections (e.g., crosswalks, stop lines, turning lane centerlines and/or boundaries, etc.) and related attributes (e.g., permissive, protected/permissive, or protected only left turn lanes; legal or illegal u-turn lanes; permissive or protected only right turn lanes; etc.). The traffic controls layer can include geospatial information of traffic signal lights, traffic signs, and other road objects and related attributes.

The AV operational database 124 can store raw AV data generated by the sensor systems 104-108, stacks 112-122, and other components of the AV 102 and/or data received by the AV 102 from remote systems (e.g., the data center 150, the client computing device 170, etc.). In some examples, the raw AV data can include HD LiDAR point cloud data, image data, RADAR data, GPS data, and other sensor data that the data center 150 can use for creating or updating AV geospatial data or for creating simulations of situations encountered by AV 102 for future testing or training of various machine learning algorithms that are incorporated in the local computing device 110.

The data center 150 can include a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and/or any other network. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes a data management platform 152, an Artificial Intelligence/Machine Learning (AI/ML) platform 154, a simulation platform 156, a remote assistance platform 158, and a ridesharing platform 160, and a map management platform 162, among other systems.

The data management platform 152 can be a “big data” system capable of receiving and transmitting data at high velocities (e.g., near real-time or real-time), processing a large variety of data and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service, map data, audio, video, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), and/or data having other characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102, including rendering geospatial information and road infrastructure (e.g., streets, lanes, crosswalks, traffic lights, stop signs, etc.) obtained from the map management platform 162 and/or a cartography platform; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system such as, for example and without limitation, a server, desktop computer, laptop computer, tablet computer, smartphone, smart wearable device (e.g., smartwatch, smart eyeglasses or other Head-Mounted Display (HMD), smart ear pods, or other smart in-ear, on-ear, or over-ear device, etc.), gaming system, or any other computing device for accessing the ridesharing application 172. In some cases, the client computing device 170 can be a customer's mobile computing device or a computing device integrated with the AV 102 (e.g., the local computing device 110). The ridesharing platform 160 can receive requests to pick up or drop off from the ridesharing application 172 and dispatch the AV 102 for the trip.

Map management platform 162 can provide a set of tools for the manipulation and management of geographic and spatial (geospatial) and related attribute data. The data management platform 152 can receive LiDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as to track specific changes that (human or machine) map editors have made to the data and to revert changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some examples, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the ridesharing application 172 to enable passengers to view the AV 102 in transit to a pick-up or drop-off location, and so on.

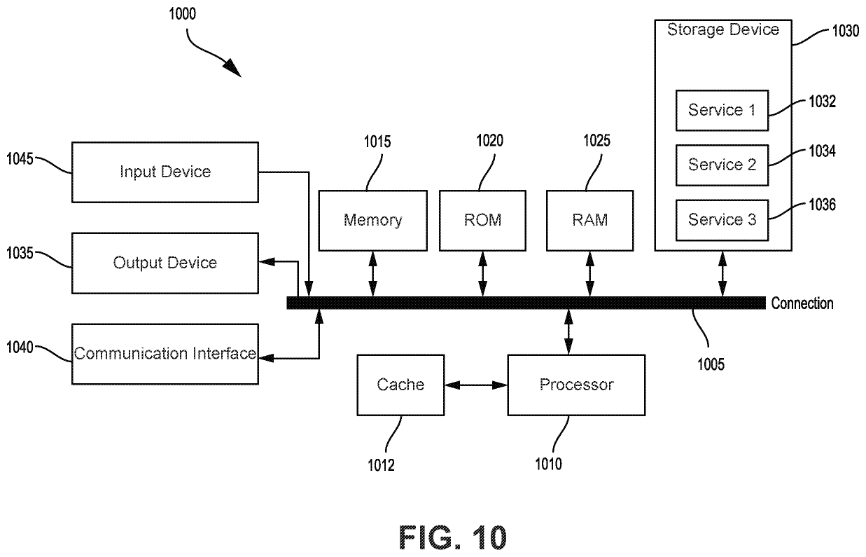

While the AV 102, the local computing device 110, and the AV environment system 100 are shown to include certain systems and components, one of ordinary skill will appreciate that the AV 102, the local computing device 110, and/or the AV environment system 100 can include more or fewer systems and/or components than those shown in FIG. 1. For example, the AV 102 can include other services than those shown in FIG. 1 and the local computing device 110 can also include, in some instances, one or more memory devices (e.g., RAM, ROM, cache, and/or the like), one or more network interfaces (e.g., wired and/or wireless communications interfaces and the like), and/or other hardware or processing devices that are not shown in FIG. 1. An illustrative example of a computing device and hardware components that can be implemented with the local computing device 110 is described below with respect to FIG. 10.

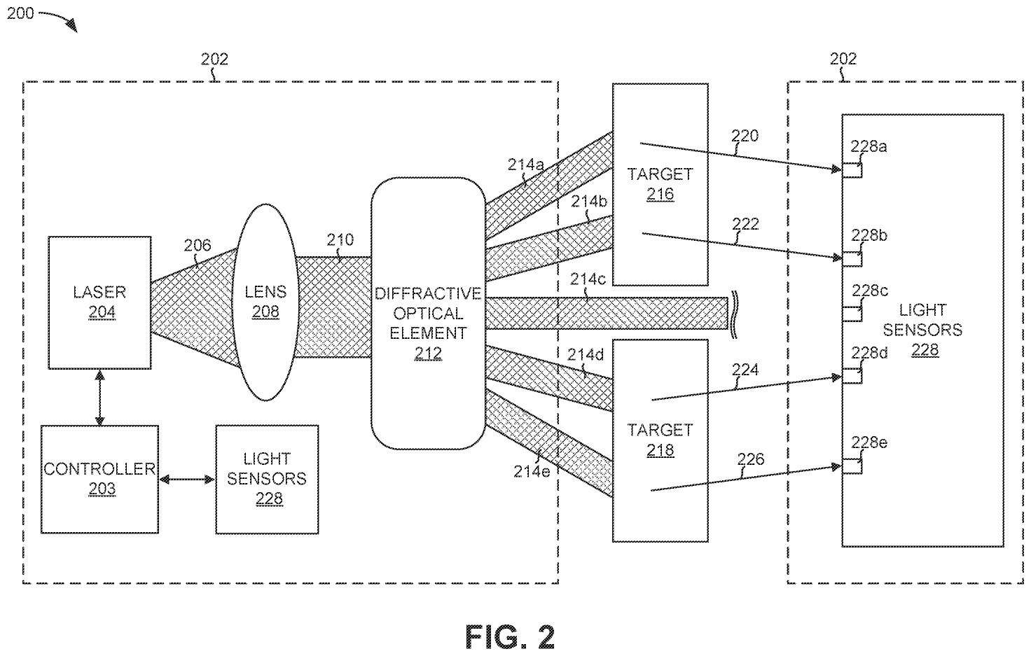

FIG. 2 is a diagram illustrating an example system 200 that includes Light Detection and Ranging (LiDAR) 202, according to some aspects of the present disclosure. In some examples, LiDAR 202 may correspond to a sensor on AV 102 (e.g., LiDAR 202 may be part of sensor systems 104-108). In some instances, LiDAR 202 may correspond to a flash imaging LiDAR that is configured to illuminate a field of view with each laser pulse and simultaneously detect reflected light from a plurality of directions (e.g., using light sensors 228).

In some aspects, LiDAR 202 can include a controller 203 (e.g., processor) that can be used to configure one or more functions or operations of LiDAR 202. For example, the controller 203 may be coupled to one or more lights sources such as laser 204 and/or to light sensors 228. In some cases, the controller 203 may be coupled to a memory (not illustrated) that may include instructions that can be executed by controller 203 for configuring and/or operating LiDAR 202 and/or any components therein.

As noted above, in some examples, LiDAR 202 can include one or more light sources such as laser 204. In some aspects, laser 204 can be configured to illuminate a field of view of LiDAR 202. For example, laser 204 may include an edge-emitting laser (EEL), a surface-emitting laser such as a vertical-cavity surface-emitting laser (VCSEL), a VCSEL array, any other type of laser, and/or any combination thereof. In some configurations, laser 204 may correspond to a VCSEL array that is electronically addressable. That is, one or more of the elements in the VCSEL array may be enabled or disabled independently.

In some aspects, laser 204 in LiDAR 202 may transmit a laser beam 206. In some examples, LiDAR 202 may include one or more optical devices that may be used to manipulate, shape, and/or steer laser beam 206. For example, LiDAR 202 may include a lens 208 that can be used to collimate laser beam 206. That is, laser beam 206 may pass through lens 208 to yield collimated laser beam 210.

In some cases, LiDAR 202 may include a diffractive beam splitter such as diffractive optical element 212. In some examples, diffractive optical element 212 can be used to create multiple beamlet groups (e.g., groups of light beams or light rays) from a laser beam. For instance, diffractive optical element 212 can be used to generate multiple beamlet groups by diffracting laser beam 210 or laser beam 206 (e.g., in configurations that omit lens 208). As illustrated, diffractive optical element 212 may be used to create beamlet group 214a, beamlet group 214b, beamlet group 214c, beamlet group 214d, and beamlet group 214e (collectively referred to as “beamlet groups 214”). In some examples, beamlet groups 214 can each include a number of tightly collimated beamlets that can be used to illuminate the scene or environment. That is, beamlet groups 214 can provide a controlled illumination pattern for LiDAR 202 that reduces or eliminates crosstalk and/or interference that may be caused by a single diffuse flash.

In some aspects, LiDAR 202 may include light sensors 228 (e.g., photodetectors, photosensors, light-sensing pixels, etc.). In some cases, light sensors 228 may include photodiodes, photoresistors, phototransistors, photovoltaic light sensors, charge-coupled device (CCD) sensors, active-pixel sensors (CMOS sensors), single-photon avalanche diode (SPAD) sensors, focal-plane arrays (FPAs), any other light sensor, and/or any combination thereof.

In some examples, light sensors 228 can be configured to receive or capture light reflections corresponding to one or more beamlets from beamlet groups 214. For instance, different subsets of light sensors 228 can be associated with different beamlet groups 214. For example, light sensor 228a can be configured to receive light reflections corresponding to beamlet group 214a; light sensor 228b can be configured to receive light reflections corresponding to beamlet group 214b; light sensor 228c can be configured to receive light reflections corresponding to beamlet group 214c; light sensor 228d can be configured to receive light reflections corresponding to beamlet group 214d; and light sensor 228e can be configured to receive light reflections corresponding to beamlet group 214e.

In some aspects, the number of beamlets in a beamlet group (e.g., beamlet groups 214) may not necessarily correspond to the number of light sensors 228 associated with a beamlet group. That is, a light sensor or pixel (e.g., light sensors 228) may correspond to multiple beamlets. In some instances, the light sensor or pixel may be overfilled or saturated. In some cases, a light sensor or pixel may receive light signals from different beamlet groups. As discussed further herein, beamlet groups may be transmitted asynchronously and/or beamlet groups may be steered in different directions such that different beamlet groups may correspond to a same set of light sensors.

As illustrated, light sensor 228a receives light signal 220, which corresponds to a reflection of a beamlet from beamlet group 214a off of target 216; light sensor 228b receives light signal 222, which corresponds to a reflection of a beamlet from beamlet group 214b off of target 216; light sensor 228d receives light signal 224, which corresponds to a reflection of a beamlet from beamlet group 214d off of target 218; and light sensor 228e receives light signal 226, which corresponds to a reflection of a beamlet from beamlet group 214e off of target 218. Further, light sensor 228c may not receive any light signal because the beamlets from beamlet group 214c did not reflect off of any object. As noted above, the beamlet groups 214 can prevent and/or reduce crosstalk and/or interference among light sensors 228.

In some cases, controller 203 may configure laser 204 to transmit multiple laser beams (e.g., laser beam 206) in order to capture a frame. In some examples, the pulse interval between laser beam transmissions may be fixed, random, or pseudorandom. In some instances, pulse intervals may be controlled but variable and/or pseudorandom. In some aspects, a secondary laser transmission may be initiated before receiving reflections corresponding to an initial laser transmission. For instance, a second laser beam 206 may be transmitted before receiving light signal 220, light signal 222, light signal 224, and/or light signal 226 (e.g., multiple beamlet groups corresponding to different laser beam transmissions may be in the air simultaneously).

In some configurations, controller 203 may configure the transmission power associated with laser 204 and/or the receiver gain associated with one or more of light sensors 228. For example, the transmission power of laser 204 can be increased to improve the signal strength of reflected signals corresponding to a Lambertian target. In another example, the transmission power of laser 204 can be decreased to minimize blooming caused by reflected signals from a retroreflective target. In another example, the receiver gain of one or more light sensors 228 can be increased to improve reception of reflected signals corresponding to a Lambertian target. In another example, the receiver gain of one or more light sensors 228 can be decreased to minimize effects of blooming caused by reflected signals from a retroreflective target.

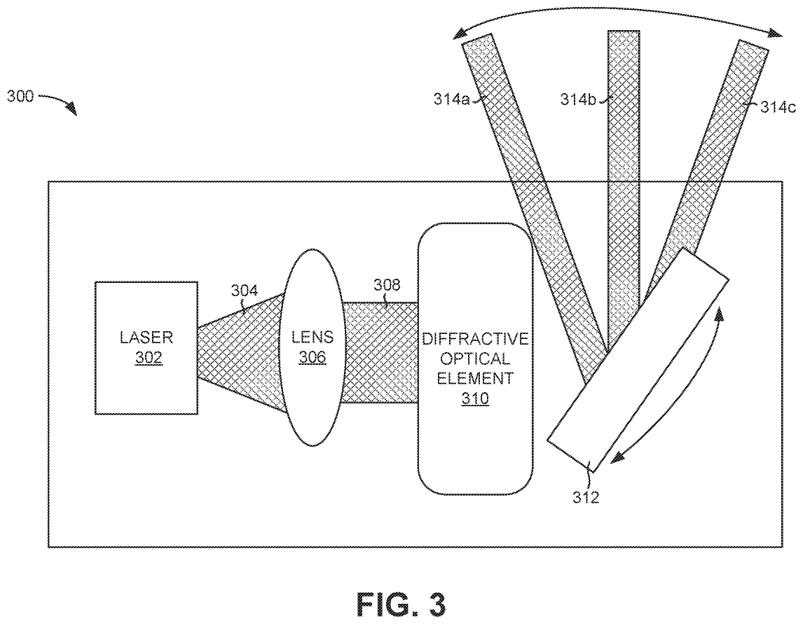

FIG. 3 illustrates an example of a LiDAR 300, according to some aspects of the present disclosure. In some aspects, LiDAR 300 may include one or more components as described in connection with LiDAR 202. For example, LiDAR 300 may include laser 302 which may correspond to laser 204. In some aspects, laser 302 may transmit laser beam 304 through lens 306 (e.g., collimating lens) to generate collimated laser beam 308. In some configurations, LiDAR 300 may also include diffractive optical element 310 that may be used to generate multiple collimated beamlet groups (e.g., beamlet group 314a, beamlet group 314b, and beamlet group 314c).

In some aspects, LiDAR 300 may include a beamlet steering device 312. In some aspects, beamlet steering device 312 can be used to steer one or more of the beamlet groups (e.g., beamlet group 314a, beamlet group 314b, and beamlet group 314c) along different elevation angles and/or azimuths. In some cases, beamlet steering device 312 may correspond to an optomechanical steering device such as Risley prism(s), micro-electromechanical systems (MEMS) mirror(s), tuning fork(s), voice coil mirror(s), rotating polygon mirror(s), and/or any other type of optomechanical steering device. For instance, beamlet steering device 312 may be used to move, oscillate, pulsate, and/or vibrate optical elements (e.g., diffractive optical element 310, lens 306, etc.) and/or transmitter elements (e.g., laser 302) in order to steer the beamlet groups (e.g., beamlet group 314a, beamlet group 314b, and beamlet group 314c) to one or more different positions. In some examples, beamlet steering device 312 may correspond to an optoelectrical steering device such as meta surfaces (e.g., meta surface scanners). In some cases, the meta surface can be based on liquid crystal technology.

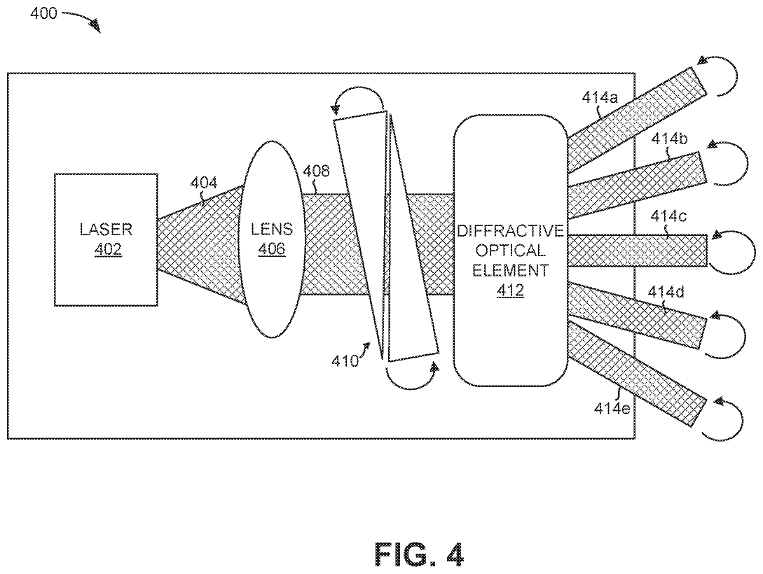

FIG. 4 illustrates an example of a LiDAR 400, according to some aspects of the present disclosure. In some aspects, LiDAR 400 may include one or more components as described in connection with LiDAR 202. For example, LiDAR 400 may include laser 402 which may correspond to laser 204. In some aspects, laser 402 may transmit laser beam 404 through lens 406 (e.g., collimating lens) to generate collimated laser beam 408.

In some configurations, LiDAR 400 may include an optomechanical steering device 410 that may be disposed between lens 406 and diffractive optical element 412. In some cases, optomechanical steering device 410 may correspond to a Riley prism. In some aspects, optomechanical steering device 410 may be used to steer, move, and/or position one or more beamlet groups such as beamlet group 414a, beamlet group 414b, beamlet group 414c, beamlet group 414d, and/or beamlet group 414e.

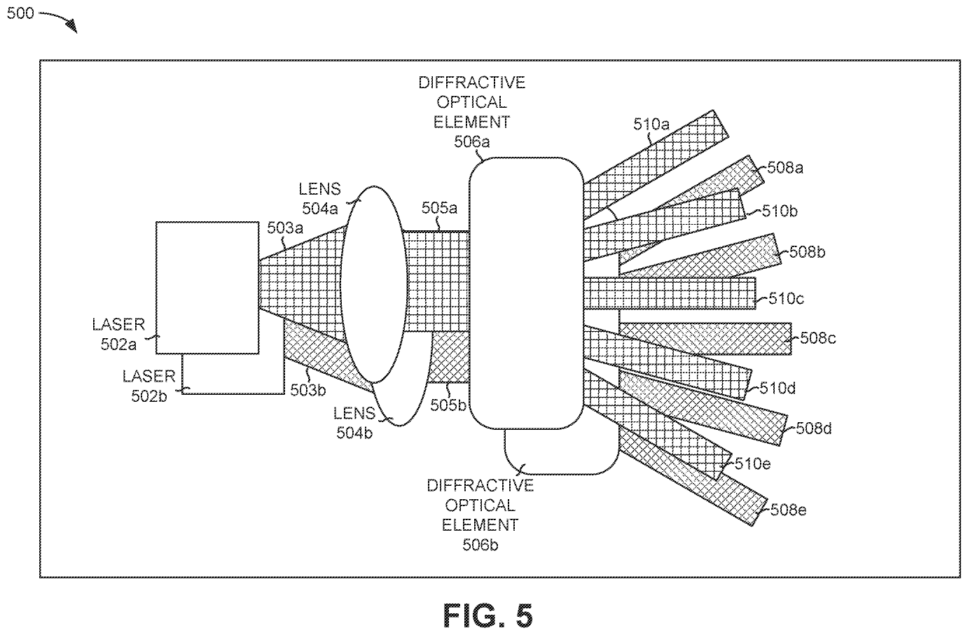

FIG. 5 illustrates an example of a LiDAR 500, according to some aspects of the present disclosure. In some aspects, LiDAR 500 may include multiple light sources such as laser 502a and laser 502b. In some cases, laser 502a and/or laser 502b may be discrete laser sources (e.g., edge emitting lasers). In some examples, laser 502a and laser 502b may correspond to elements from a VCSEL array.

In some examples, laser 502a and laser 502b can be used to generate different sets of collimated beamlet groups. For example, laser 502a may transmit a laser beam 503a through lens 504a (e.g., collimating lens) and the collimated laser beam 505a may be directed through diffractive optical element 506a to generate beamlet group 510a, beamlet group 510b, beamlet group 510c, beamlet group 510d, and beamlet group 510e (collectively referred to as “beamlet groups 510”). In another example, laser 502b may transmit a laser beam 503b through lens 504b (e.g., collimating lens) and the collimated laser beam 505b may be directed through diffractive optical element 506b to generate beamlet group 508a, beamlet group 508b, beamlet group 508c, beamlet group 508d, and beamlet group 508e (collectively referred to as “beamlet groups 508”).

It is noted that in some configurations, LiDAR 500 may include additional components not illustrated in FIG. 5. For example, LiDAR 500 may include a beamlet steering device such as beamlet steering device 312. LiDAR 500 may also include one or more processors, memories, light sensors, optical devices, etc. Also, in some aspects, LiDAR 500 may be implemented without one or more of the components illustrated in FIG. 5. For instance, diffractive optical element 506a and/or diffractive optical element 506b may be excluded when the laser source (e.g., laser 502a and/or laser 502b) corresponds to a VCSEL array.

In some aspects, LiDAR 500 may be configured such that beamlet groups 508 and beamlet groups 510 are interlaced (e.g., interleaved). In one illustrative example, beamlet group 508a from beamlet groups 508 may be positioned between beamlet group 510a and beamlet group 510b from beamlet groups 510. In some cases, laser 502a and laser 502b may be configured to transmit laser beams (e.g., laser beam 503a and laser beam 503b, respectively) asynchronously and/or at different pulse intervals. That is, in some cases, the pulse interval between consecutive pulses from a single laser (e.g., laser 502a or laser 502b) may be varied. In another example, the pulse interval between pulses from different lasers may also be varied. In some examples, the pulse intervals may be fixed, random, pseudorandom, or sequenced to minimize the probability of simultaneous pulses (e.g., simultaneous transmission by laser 502a and laser 502b).

In some aspects, transmission by laser 502a and laser 502b may be staggered in time but not isolated. That is, laser beam 503b from laser 502b may be transmitted after laser beam 503a from laser 502a while the pulses from laser 502a are still in the air. In some cases, the variation in pulse interval can be used to identify the correct pulses and accumulate them at the corresponding light sensor(s) (e.g., light sensors 228). In some aspects, the variation in pulse interval may be used to discard pulses that are received by a light sensor or pixel (e.g., the pulse interval can be used to identify the beamlet group to accumulate the pulse or discard the pulse).

In some configurations, the transmission power associated with laser 502a and/or laser 502b can be configured. In some cases, the transmission power associated with laser 502a may be different from the transmission power associated with laser 502b. In some aspects, the receiver gain associated with the light sensors (not illustrated) corresponding to beamlet groups 508 and/or beamlet groups 510 may be configured. In some examples, the receiver gain associated with the light sensors that are configured to receive reflections corresponding to beamlet groups 508 can be different from the receiver gain associated with the light sensors that are configured to receive reflections corresponding to beamlet groups 510.

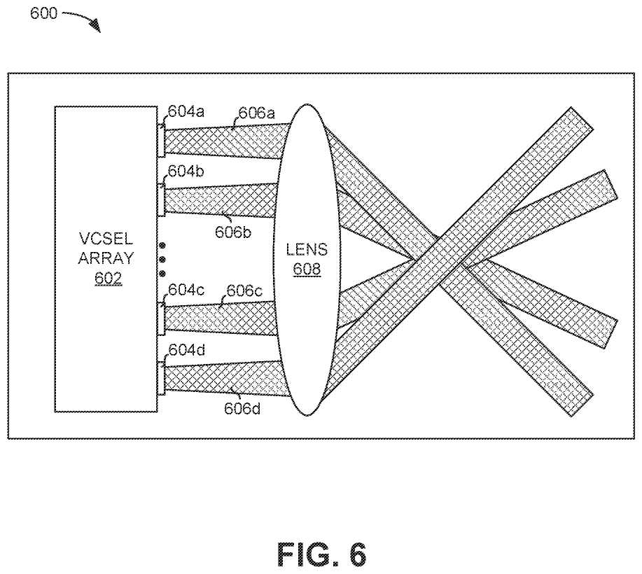

FIG. 6 illustrates an example of a LiDAR 600, according to some aspects of the present disclosure. In some aspects, LiDAR 600 may include one or more vertical-cavity surface-emitting laser (VCSEL) arrays such as VCSEL array 602. In some aspects, VCSEL array 602 may include any number of VCSEL array elements such as VCSEL element 604a, VCSEL element 604b, VCSEL element 604c, and VCSEL element 604d (e.g., collectively referred to as “VCSEL elements 604”).

In some cases, VCSEL elements 604 may be electronically addressable. For instance, LiDAR 600 may be configured to independently fire beamlets from one or more of VCSEL elements 604. As illustrated, VCSEL element 604a may fire beamlet 606a; VCSEL element 604b may fire beamlet 606b; VCSEL element 604c may fire beamlet 606c; and VCSEL element 604d may fire beamlet 606d. In some examples, different sets of array elements from VCSEL array 602 may be associated with different beamlet groups. For instance, VCSEL element 604a and VCSEL element 604c may be associated with a first beamlet group, and VCSEL element 604b and VCSEL element 604d may be associated with a second beamlet group.

In some configurations, VCSEL array 602 may be configured to fire one or more beamlets and/or one or more beamlet groups at different times. In one illustrative example, beamlet 606a may be fired at the same time as beamlet 606c, and beamlet 606b may be fired at the same time as beamlet 606d (e.g., the beamlet groups can be configured to have interlaced beamlets).

In some instances, LiDAR 600 may include one or more optical elements such as lens 608. In some cases, lens 608 may correspond to a collimating lens. In some examples, lens 608 can be used to direct one or more of beamlets (e.g., beamlet 606a, beamlet 606b, beamlet 606c, and/or beamlet 606d) in different directions.

It is noted that in some configurations, LiDAR 600 may include additional components not illustrated in FIG. 6. For example, LiDAR 600 may include a beamlet steering device such as beamlet steering device 312. LiDAR 600 may also include one or more processors, memories, light sensors, optical devices, etc.

In some configurations, the transmission power associated with VCSEL elements 604 can be configured. That is, the transmission power associated with beamlet 606a may be different from the transmission power associated with beamlet 606b. In some aspects, the receiver gain associated with the light sensors (not illustrated) corresponding to one or more of the beamlets (e.g., beamlet 606a, beamlet 606b, beamlet 606c, and/or beamlet 606d) may be configured. In some examples, the receiver gain associated with the light sensors that are configured to receive reflections corresponding to a first beamlet group (e.g., beamlet 606a and beamlet 606c) can be different from the receiver gain associated with the light sensors that are configured to receive reflections corresponding to a second beamlet groups (e.g., beamlet 606b and beamlet 606d).

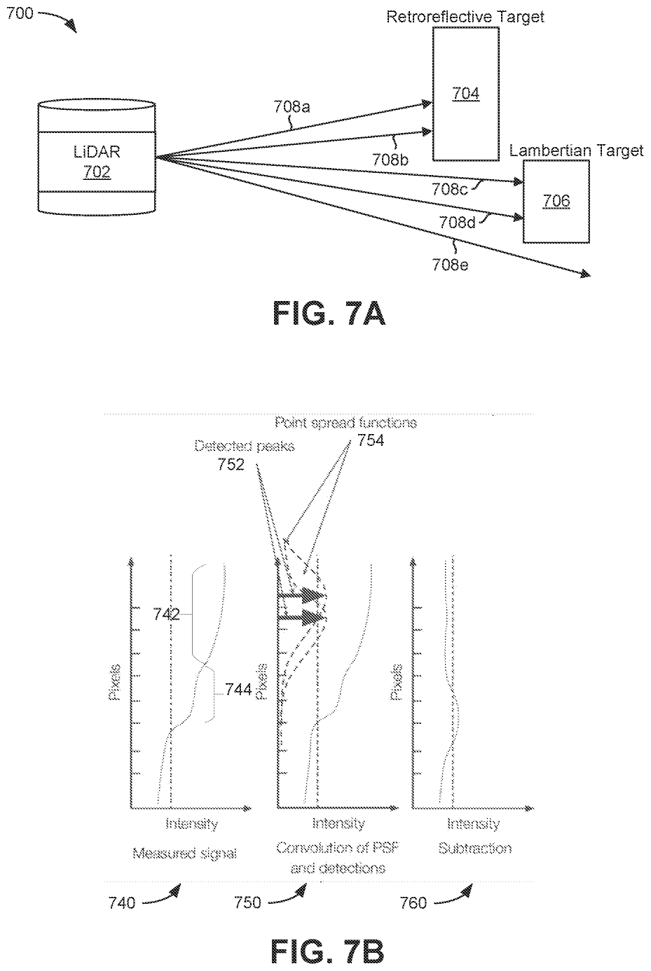

FIG. 7A is a diagram illustrating an example system 700 that includes a LiDAR 702. In some aspects, LiDAR 702 may correspond to LiDAR 202, LiDAR 300, LiDAR 400, or LiDAR 500, as described herein. In some cases, LiDAR 702 can transmit one or more beamlets or beamlet groups that may cause reflections from one or more targets. For example, LiDAR 702 may transmit beamlet 708a and beamlet 708b that reflect from retroreflective target 704; LiDAR 702 may transmit beamlet 708c and beamlet 708d that reflect from Lambertian target 706; and LiDAR 702 may transmit beamlet 708e that does not cause any reflections (e.g., does not hit any targets). In some cases, beamlet 708a, beamlet 708b, beamlet 708c, beamlet 708d, and beamlet 708e may be transmitted simultaneously. In some cases, beamlet 708a, beamlet 708b, beamlet 708c, beamlet 708d, and beamlet 708e can be part of separate beamlet groups that may be transmitted at different time (e.g., asynchronously).

In some examples, LiDAR 702 can use spatiotemporal point spread function(s) to process the received (e.g., reflected) light signals and reduce/mitigate the effect of crosstalk or blooming.

FIG. 7B illustrates a set of intensity plots associated with LiDAR 702 in system 700. For example, plot 740 illustrates the intensity plot based on measured reflections corresponding to beamlet 708a, beamlet 708b, beamlet 708c, beamlet 708d, and beamlet 708e. In some aspects, plot 740 demonstrates the effect of blooming as the pixels 742 corresponding to retroreflective target 704 (e.g., beamlet 708a and beamlet 708b) may be saturated and cause blooming because the charge fills or contributes to adjacent pixels 744 corresponding to Lambertian target 706. Based on plot 740, LiDAR 702 may not distinguish two separate targets (e.g., target 704 and target 706).

In some cases, LiDAR 702 may detect retroreflective target 704 based on the intensity measurements associated with pixels 742. For instance, plot 750 identifies the detected peaks 752 that correspond to reflections from beamlet 708a and beamlet 708b. In some examples, LiDAR 702 may perform a convolution of detected peaks 752 and point spread functions (PSFs) 754 to determine a signal that can be subtracted from the measured intensity plot (e.g., plot 740) to yield plot 760, which corresponds to a distinct detection of Lambertian target 706.

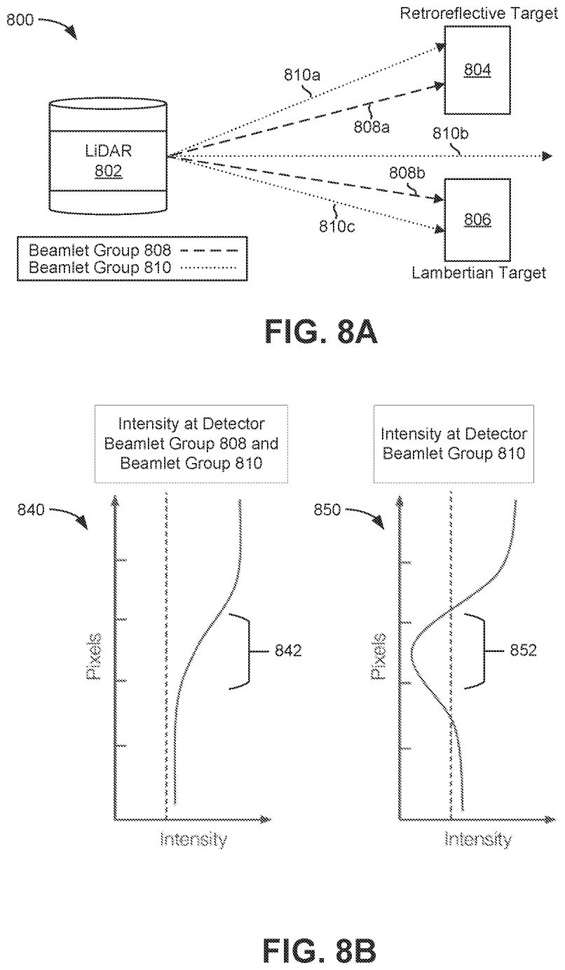

FIG. 8A is a diagram illustrating an example system 800 that includes a LiDAR 802. In some aspects, LiDAR 802 may correspond to LiDAR 202, LiDAR 300, LiDAR 400, or LiDAR 500, as described herein. In some cases, LiDAR 802 can transmit one or more beamlets or beamlet groups that may cause reflections from one or more targets. For example, LiDAR 802 may transmit beamlet group 808 that can include beamlet 808a and beamlet 808b; and LiDAR 802 may transmit beamlet group 810 that can include beamlet 810a, beamlet 810b, and beamlet 810c. As illustrated, beamlet 810a from beamlet group 810 and beamlet 808a from beamlet group 808 each reflect from retroreflective target 804; beamlet 810b from beamlet group 810 does not hit any target; and beamlet 808b from beamlet group 808 and beamlet 810c from beamlet group 810 each reflect from Lambertian target 806. In some examples, beamlet group 808 and beamlet group 810 may be transmitted at the same time, and in some cases, beamlet group 808 and beamlet group 810 may be transmitted at different times (e.g., using different laser sources or a VCSEL array to generate temporally staggered pulses).

FIG. 8B illustrates a set of intensity plots associated with LiDAR 802 in system 800. For example, plot 840 illustrates the intensity plot based on measured reflections corresponding to beamlet group 808 (e.g., beamlet 808a and beamlet 808b) and beamlet group 810 transmitted at or about the same time (e.g., simultaneous illumination). In some aspects, plot 840 may include a false positive detection at pixels 842 (e.g., location corresponding to beamlet 810b), which may be caused by blooming from the reflected signal from the retroreflective target 804 (e.g., beamlet 808a).

In some aspects, plot 850 illustrates the intensity plot based on measured reflections corresponding to beamlet group 810 (e.g., beamlet 810a, beamlet 810b, beamlet 810c), which can be fired separately from beamlet group 808. In some cases, plot 850 may indicate that a true negative (e.g., no target is present) is detected at pixels 852 based on the lack of a return corresponding to beamlet 810b. In some instances, LiDAR 802 may use plot 850 (e.g., data from beamlet group 810) to identify the false positive in plot 840 and mitigate the effects of blooming.

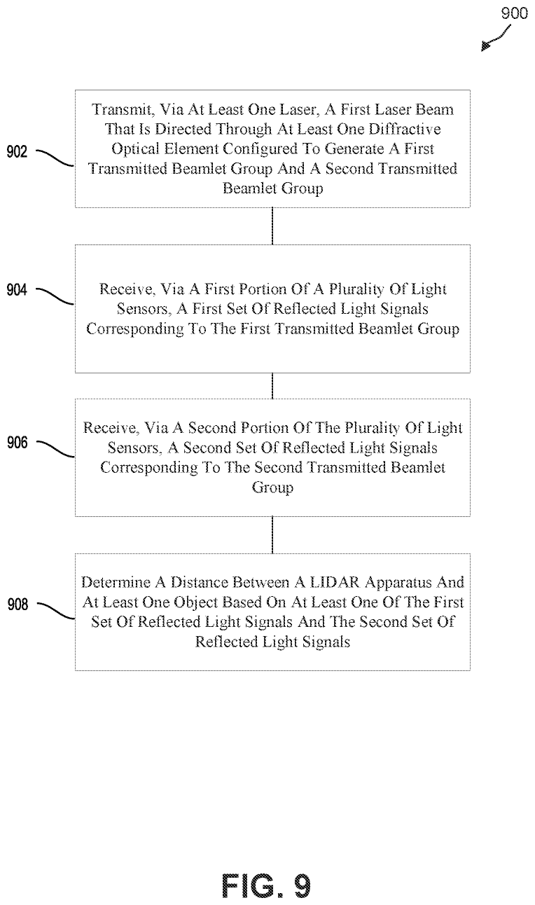

FIG. 9 illustrates a flowchart of an example process 900 for operating a flash LiDAR to mitigate crosstalk and interference. At step 902, the process 900 includes transmitting, via at least one laser, a first laser beam that is directed through at least one diffractive optical element configured to generate a first transmitted beamlet group and a second transmitted beamlet group. For example, LiDAR 202 can use laser 204 to transmit laser beam 206 that is directed through diffractive optical element 212 to generate beamlet groups 214. In some cases, the at least one laser can correspond to a vertical cavity surface-emitting laser (VCSEL) array.

At step 904, the process 900 includes receiving, via a first portion of a plurality of light sensors, a first set of reflected light signals corresponding to the first transmitted beamlet group. For example, LiDAR 202 can receive, via light sensor 228a, light signal 220 corresponding to a reflection of beamlet group 214a. In some aspects, the plurality of light sensors can correspond to a plurality of single-photon avalanche diodes (SPADs).

At step 906, the process 900 includes receiving, via a second portion of the plurality of light sensors, a second set of reflected light signals corresponding to the second transmitted beamlet group. For instance, LiDAR 202 can receive, via light sensor 228b, light signal 222 corresponding to a reflection of beamlet group 214b.

At step 908, the process 900 includes determining a distance between the LIDAR apparatus and at least one object based on at least one of the first set of reflected light signals and the second set of reflected light signals. For instance, LiDAR 202 can determine a distance between LiDAR 202 and target 216 based on light signal 220 and/or light signal 222.

In some aspects, the process 900 may include receiving, via a first light sensor from the first portion of the plurality of light sensors, at least one reflected light signal from the second set of reflected light signals corresponding to the second transmitted beamlet group; and determining that the at least one reflected light signal from the second set of reflected light signals was received by the first light sensor due to a crosstalk condition, wherein the crosstalk condition includes at least one of electrical crosstalk, optical crosstalk, and light sensor saturation. For example, LiDAR 202 may receive, via light sensor 228c, light energy associated with light signal 222 corresponding to beamlet group 214b. In some cases, LiDAR 202 may determine that the light energy received at light sensor 228c is due to a crosstalk condition such as a saturation of light sensor 228b (e.g., due to blooming effect). In some aspects, LiDAR 202 may utilize techniques described in connection with FIGS. 7A, 7B, 8A, and 8B to determine that blooming has occurred. In some examples, LiDAR 202 may determine that the light energy received at light sensor 228c is due to a crosstalk condition such as electrical crosstalk or optical crosstalk. For instance, optical crosstalk can be caused by the optical subsystem (e.g., lens 208) or the light sensors 228. In some cases, optical crosstalk may be induced by stray light reflected off of the LiDAR housing, windscreen, or other external surface and/or by atmospheric conditions such as fog or rain.

In some cases, the process 900 may include transmitting, via the at least one laser, a second laser beam through the at least one diffractive optical element to generate a third transmitted beamlet group and a fourth transmitted beamlet group, wherein a pulse interval between the first laser beam and the second laser beam is a random amount of time. For example, laser 204 may be configured to transmit a second laser beam (e.g., subsequent to laser beam 206) that generates new beamlet groups (e.g., subsequent to beamlet groups 214). In some cases, the second laser beam is transmitted prior to receiving the first set of reflected light signals corresponding to the first transmitted beamlet group. For example, laser 204 can be configured to transmit a second laser beam before light sensors 228 receive the reflected light signals (e.g., light signal 220, light signal 222, light signal 224, and light signal 226) corresponding to beamlet groups 214.

In some examples, the at least one laser can comprise a first laser and a second laser, and the first transmitted beamlet group can correspond to the first laser beam transmitted via the first laser and the second transmitted beamlet group can correspond to a second laser beam transmitted via the second laser. For example, LiDAR 500 can include laser 502a and laser 502b, and beamlet groups 510 can correspond to laser 502a and beamlet groups 508 can correspond to laser 502b. In some aspects, one or more beamlets from the first transmitted beamlet group are interlaced with one or more beamlets from the second transmitted beamlet group. For example, one or more beamlets from beamlet groups 510 can be interlaced with one or more beamlets from beamlet groups 508.

In some examples, the process 900 can include transmitting, via the first laser, the first transmitted beamlet group at a first time; and transmitting, via the second laser, the second transmitted beamlet group at a second time occurring after the first time. For example, laser 502a can be configured to transmit beamlet groups 510 at a first time and laser 502b can be configured to transmit beamlet groups 508 at a second time occurring after the first time.

In some aspects, the process 900 can include configuring a first transmission power for the first laser beam and a second transmission power for the second laser beam, wherein the first transmission power is different than then second transmission power. For example, laser 502a can be configured to have a first transmission power and laser 502b can be configured to have a second transmission power. In some examples, the process 900 can include configuring a first receiver gain for the first portion of the plurality of light sensors and a second receiver gain for the second portion of the plurality of light sensors, wherein the first receiver gain is different than the second receiver gain. For example, a first portion of light sensors 228 can be configured to have a first receive gain and a second portion of light sensors 228 can be configured to have a second receiver gain that is different than the first receiver gain.

In some cases, the process 900 can include steering, via at least one beamlet steering device, the first transmitted beamlet group in a first direction and the second transmitted beamlet group in a second direction. In some aspects, the at least one beamlet steering device can include at least one of a Risley prism, a micro-electromechanical systems (MEMS) mirror, a tuning fork, a voice coil mirror (VCM), and a metasurface scanner. For example, beamlet steering device 312 can be used to steer beamlet group 314a in a first direction and beamlet group 314b in a second direction.

FIG. 10 illustrates an example processor-based system with which some aspects of the subject technology can be implemented. For example, processor-based system 1000 can be any computing device making up local computing device 110, client computing device 170, a passenger device executing the ridesharing application 172, or any component thereof in which the components of the system are in communication with each other using connection 1005. Connection 1005 can be a physical connection via a bus, or a direct connection into processor 1010, such as in a chipset architecture. Connection 1005 can also be a virtual connection, networked connection, or logical connection.

In some examples, computing system 1000 is a distributed system in which the functions described in this disclosure can be distributed within a datacenter, multiple data centers, a peer network, etc. In some cases, one or more of the described system components represents many such components each performing some or all of the function for which the component is described. In some cases, the components can be physical or virtual devices.

Example system 1000 includes at least one processing unit (CPU or processor) 1010 and connection 1005 that couples various system components including system memory 1015, such as read-only memory (ROM) 1020 and random-access memory (RAM) 1025 to processor 1010. Computing system 1000 can include a cache of high-speed memory 1012 connected directly with, in close proximity to, and/or integrated as part of processor 1010.

Processor 1010 can include any general-purpose processor and a hardware service or software service, such as services 1032, 1034, and 1036 stored in storage device 1030, configured to control processor 1010 as well as a special-purpose processor where software instructions are incorporated into the actual processor design. Processor 1010 may essentially be a completely self-contained computing system, containing multiple cores or processors, a bus, memory controller, cache, etc. A multi-core processor may be symmetric or asymmetric.

To enable user interaction, computing system 1000 can include an input device 1045, which can represent any number of input mechanisms, such as a microphone for speech, a touch-sensitive screen for gesture or graphical input, keyboard, mouse, motion input, speech, etc. Computing system 1000 can also include output device 1035, which can be one or more of a number of output mechanisms known to those of skill in the art. In some instances, multimodal systems can enable a user to provide multiple types of input/output to communicate with computing system 1000. Computing system 1000 can include communications interface 1040, which can generally govern and manage the user input and system output. The communication interface may perform or facilitate receipt and/or transmission wired or wireless communications via wired and/or wireless transceivers, including those making use of an audio jack/plug, a microphone jack/plug, a universal serial bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a radio-frequency identification (RFID) wireless signal transfer, near-field communications (NFC) wireless signal transfer, dedicated short range communication (DSRC) wireless signal transfer, 802.11 Wi-Fi wireless signal transfer, wireless local area network (WLAN) signal transfer, Visible Light Communication (VLC), Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer, ultraviolet light signal transfer, wireless signal transfer along the electromagnetic spectrum, or some combination thereof.

Communications interface 1040 may also include one or more Global Navigation Satellite System (GNSS) receivers or transceivers that are used to determine a location of the computing system 1000 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 1030 can be a non-volatile and/or non-transitory computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a compact disc read only memory (CD-ROM) optical disc, a rewritable compact disc (CD) optical disc, digital video disk (DVD) optical disc, a blu-ray disc (BDD) optical disc, a holographic optical disk, another optical medium, a secure digital (SD) card, a micro secure digital (microSD) card, a Memory Stick® card, a smartcard chip, a EMV chip, a subscriber identity module (SIM) card, a mini/micro/nano/pico SIM card, another integrated circuit (IC) chip/card, random access memory (RAM), static RAM (SRAM), dynamic RAM (DRAM), read-only memory (ROM), programmable read-only memory (PROM), erasable programmable read-only memory (EPROM), electrically erasable programmable read-only memory (EEPROM), flash EPROM (FLASHEPROM), cache memory (L1/L2/L3/L4/L5/L #), resistive random-access memory (RRAM/ReRAM), phase change memory (PCM), spin transfer torque RAM (STT-RAM), another memory chip or cartridge, and/or a combination thereof.

Storage device 1030 can include software services, servers, services, etc., that when the code that defines such software is executed by the processor 1010, causes the system to perform a function. In some examples, a hardware service that performs a particular function can include the software component stored in a computer-readable medium in connection with the necessary hardware components, such as processor 1010, connection 1005, output device 1035, etc., to carry out the function.

Aspects within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special-purpose computer, or special-purpose processing device to perform a certain function or group of functions. By way of example, computer-executable instructions can be used to implement perception system functionality for determining when sensor cleaning operations are needed or should begin. Computer-executable instructions can also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other examples of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Aspects of the disclosure may also be practiced in distributed computing environments where tasks are performed by local and remote processing devices that are linked (either by hardwired links, wireless links, or by a combination thereof) through a communications network. In a distributed computing environment, program modules can be located in both local and remote memory storage devices.

The various examples described above are provided by way of illustration only and should not be construed to limit the scope of the disclosure. For example, the principles herein apply equally to optimization as well as general improvements. Various modifications and changes may be made to the principles described herein without following the example aspects and applications illustrated and described herein, and without departing from the spirit and scope of the disclosure.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:
Aspect 1. A method comprising: transmitting, via at least one laser, a first laser beam that is directed through at least one diffractive optical element configured to generate a first transmitted beamlet group and a second transmitted beamlet group; receiving, via a first portion of a plurality of light sensors, a first set of reflected light signals corresponding to the first transmitted beamlet group; receiving, via a second portion of the plurality of light sensors, a second set of reflected light signals corresponding to the second transmitted beamlet group; and determining a distance between the LiDAR apparatus and at least one object based on at least one of the first set of reflected light signals and the second set of reflected light signals.

Aspect 2. The method of Aspect 1, further comprising: receiving, via a first light sensor from the first portion of the plurality of light sensors, at least one reflected light signal from the second set of reflected light signals corresponding to the second transmitted beamlet group; and determining that the at least one reflected light signal from the second set of reflected light signals was received by the first light sensor due to a crosstalk condition, wherein the crosstalk condition includes at least one of electrical crosstalk, optical crosstalk, and light sensor saturation.

Aspect 3. The method of any of Aspects 1 to 2, further comprising: transmitting, via the at least one laser, a second laser beam through the at least one diffractive optical element to generate a third transmitted beamlet group and a fourth transmitted beamlet group, wherein a pulse interval between the first laser beam and the second laser beam is a random amount of time.

Aspect 4. The method of Aspect 3, wherein the second laser beam is transmitted prior to receiving the first set of reflected light signals corresponding to the first transmitted beamlet group.

Aspect 5. The method of any of Aspects 1 to 4, wherein the at least one laser comprises a first laser and a second laser, and wherein the first transmitted beamlet group corresponds to the first laser beam transmitted via the first laser and the second transmitted beamlet group corresponds to a second laser beam transmitted via the second laser.

Aspect 6. The method of Aspect 5, wherein one or more beamlets from the first transmitted beamlet group are interlaced with one or more beamlets from the second transmitted beamlet group.

Aspect 7. The method of any of Aspects 5 to 6, further comprising configuring a first transmission power for the first laser beam and a second transmission power for the second laser beam, wherein the first transmission power is different than then second transmission power.

Aspect 8. The method of any of Aspects 5 to 7, further comprising configuring a first receiver gain for the first portion of the plurality of light sensors and a second receiver gain for the second portion of the plurality of light sensors, wherein the first receiver gain is different than the second receiver gain.

Aspect 9. The method of any of Aspects 5 to 8, further comprising transmitting, via the first laser, the first transmitted beamlet group at a first time; and transmitting, via the second laser, the second transmitted beamlet group at a second time occurring after the first time.

Aspect 10. The method of any of Aspects 1 to 9, further comprising steering, via at least one beamlet steering device, the first transmitted beamlet group in a first direction and the second transmitted beamlet group in a second direction.

Aspect 11. The method of Aspect 10, wherein the at least one beamlet steering device includes at least one of a Risley prism, a micro-electromechanical systems (MEMS) mirror, a tuning fork, a voice coil mirror (VCM), and a metasurface scanner.

Aspect 12. The method of any of Aspects 1 to 11, wherein the at least one laser corresponds to a vertical cavity surface-emitting laser (VCSEL) array.

Aspect 13. The method of any of Aspects 1 to 12, wherein the plurality of light sensors corresponds to a plurality of single-photon avalanche diodes (SPADs).

Aspect 14. An apparatus comprising: at least one laser; at least one diffractive optical element; a plurality of light sensors; and at least one memory; and at least one processor coupled to the at least one laser, the plurality of light sensors, and the at least one memory, wherein the at least one processor is configured to perform operations in accordance with any one of Aspects 1 to 13.

Aspect 15. An apparatus comprising means for performing operations in accordance with any one of Aspects 1 to 13.

Aspect 16. A non-transitory computer-readable medium comprising instructions that, when executed by an apparatus, cause the apparatus to perform operations in accordance with any one of Aspects 1 to 13.

Aspect 17. A method comprising: transmitting, via a first set of elements from a vertical cavity surface-emitting laser (VCSEL) array, a first transmitted beamlet group; transmitting, via a second set of elements from the VCSEL array, a second transmitted beamlet group; receiving, via a first portion of a plurality of light sensors, a first set of reflected light signals corresponding to the first transmitted beamlet group; receiving, via a second portion of the plurality of light sensors, a second set of reflected light signals corresponding to the second transmitted beamlet group; and determining a distance between the LiDAR apparatus and at least one object based on at least one of the first set of reflected light signals and the second set of reflected light signals.

Aspect 18. The method of Aspect 17, wherein the first transmitted beamlet group and the second transmitted beamlet group are transmitted at different times.

Aspect 19. An apparatus comprising: a vertical cavity surface-emitting laser (VCSEL) array; a plurality of light sensors; and at least one memory; and at least one processor coupled to the VCSEL array, the plurality of light sensors, and the at least one memory, wherein the at least one processor is configured to perform operations in accordance with any one of Aspects 17 to 18.

Aspect 20. An apparatus comprising means for performing operations in accordance with any one of Aspects 17 to 18.

Aspect 21. A non-transitory computer-readable medium comprising instructions that, when executed by an apparatus, cause the apparatus to perform operations in accordance with any one of Aspects 17 to 18.

What is claimed is:

1. A light detection and ranging (LiDAR) apparatus, comprising:
at least one laser;
at least one diffractive optical element;
a plurality of light sensors;
at least one memory comprising instructions; and
at least one processor coupled to the at least one laser, the plurality of light sensors, and the at least one memory, wherein the at least one processor is configured to execute the instructions and cause the LiDAR apparatus to:
transmit, via the at least one laser, a first laser beam through the at least one diffractive optical element to generate a first transmitted beamlet group and a second transmitted beamlet group;
receive, via a first portion of the plurality of light sensors, a first set of reflected light signals corresponding to the first transmitted beamlet group;
receive, via a second portion of the plurality of light sensors, a second set of reflected light signals corresponding to the second transmitted beamlet group; and
determine a distance between the LiDAR apparatus and at least one object based on at least one of the first set of reflected light signals and the second set of reflected light signals.

2. The LiDAR apparatus of claim 1, wherein the at least one processor is further configured to cause the LiDAR apparatus to:
receive, via a first light sensor from the first portion of the plurality of light sensors, at least one reflected light signal from the second set of reflected light signals corresponding to the second transmitted beamlet group; and
determine that the at least one reflected light signal from the second set of reflected light signals was received by the first light sensor due to a crosstalk condition, wherein the crosstalk condition includes at least one of electrical crosstalk, optical crosstalk, and light sensor saturation.

3. The LiDAR apparatus of claim 1, wherein the at least one processor is further configured to cause the LiDAR apparatus to:
transmit, via the at least one laser, a second laser beam through the at least one diffractive optical element to generate a third transmitted beamlet group and a fourth transmitted beamlet group, wherein a pulse interval between the first laser beam and the second laser beam is a random amount of time.

4. The LiDAR apparatus of claim 3, wherein the second laser beam is transmitted prior to receiving the first set of reflected light signals corresponding to the first transmitted beamlet group.

5. The LiDAR apparatus of claim 1, wherein the at least one laser comprises a first laser and a second laser, and wherein the first transmitted beamlet group corresponds to the first laser beam transmitted via the first laser and the second transmitted beamlet group corresponds to a second laser beam transmitted via the second laser.

6. The LiDAR apparatus of claim 5, wherein one or more beamlets from the first transmitted beamlet group are interlaced with one or more beamlets from the second transmitted beamlet group.

7. The LiDAR apparatus of claim 5, wherein the at least one processor is further configured to cause the LiDAR apparatus to:
configure a first transmission power for the first laser beam and a second transmission power for the second laser beam, wherein the first transmission power is different than then second transmission power.

8. The LiDAR apparatus of claim 5, wherein the at least one processor is further configured to cause the LiDAR apparatus to:
configure a first receiver gain for the first portion of the plurality of light sensors and a second receiver gain for the second portion of the plurality of light sensors, wherein the first receiver gain is different than the second receiver gain.

9. The LiDAR apparatus of claim 5, wherein the at least one processor is further configured to cause the LiDAR apparatus to:
transmit, via the first laser, the first transmitted beamlet group at a first time; and
transmit, via the second laser, the second transmitted beamlet group at a second time occurring after the first time.

10. The LiDAR apparatus of claim 1, further comprising:
at least one beamlet steering device configured to steer the first transmitted beamlet group in a first direction and the second transmitted beamlet group in a second direction.

11. The LiDAR apparatus of claim 10, wherein the at least one beamlet steering device includes at least one of a Risley prism, a micro-electromechanical systems (MEMS) mirror, a tuning fork, a voice coil mirror (VCM), and a metasurface scanner.

12. The LiDAR apparatus of claim 1, wherein the at least one laser corresponds to a vertical cavity surface-emitting laser (VCSEL) array.

13. The LiDAR apparatus of claim 1, wherein the plurality of light sensors corresponds to a plurality of single-photon avalanche diodes (SPADs).

14. A method of operating a light detection and ranging (LiDAR) apparatus, comprising:
transmitting, via at least one laser, a first laser beam that is directed through at least one diffractive optical element configured to generate a first transmitted beamlet group and a second transmitted beamlet group;
receiving, via a first portion of a plurality of light sensors, a first set of reflected light signals corresponding to the first transmitted beamlet group;
receiving, via a second portion of the plurality of light sensors, a second set of reflected light signals corresponding to the second transmitted beamlet group; and
determining a distance between the LiDAR apparatus and at least one object based on at least one of the first set of reflected light signals and the second set of reflected light signals.

15. The method of claim 14, further comprising:
receiving, via a first light sensor from the first portion of the plurality of light sensors, at least one reflected light signal from the second set of reflected light signals corresponding to the second transmitted beamlet group; and
determining that the at least one reflected light signal from the second set of reflected light signals was received by the first light sensor due to a crosstalk condition, wherein the crosstalk condition includes at least one of electrical crosstalk, optical crosstalk, and light sensor saturation.

16. The method of claim 14, further comprising:
transmitting, via the at least one laser, a second laser beam through the at least one diffractive optical element to generate a third transmitted beamlet group and a fourth transmitted beamlet group, wherein a pulse interval between the first laser beam and the second laser beam is a random amount of time.

17. The method of claim 16, wherein the second laser beam is transmitted prior to receiving the first set of reflected light signals corresponding to the first transmitted beamlet group.

18. The method of claim 14, wherein the at least one laser comprises a first laser and a second laser, and wherein the first transmitted beamlet group corresponds to the first laser beam transmitted via the first laser and the second transmitted beamlet group corresponds to a second laser beam transmitted via the second laser.

19. The method of claim 18, wherein one or more beamlets from the first transmitted beamlet group are interlaced with one or more beamlets from the second transmitted beamlet group.

20. A light detection and ranging (LiDAR) apparatus, comprising:
a vertical-cavity surface-emitting laser (VCSEL) array;
a plurality of light sensors;
at least one memory comprising instructions; and
at least one processor coupled to the VCSEL array, the plurality of light sensors, and the at least one memory, wherein the at least one processor is configured to execute the instructions and cause the LiDAR apparatus to:
transmit, via a first set of VCSEL array elements from the VCSEL array, a first transmitted beamlet group;
transmit, via a second set of VCSEL array elements from the VCSEL array, a second transmitted beamlet group;
receive, via a first portion of the plurality of light sensors, a first set of reflected light signals corresponding to the first transmitted beamlet group;
receive, via a second portion of the plurality of light sensors, a second set of reflected light signals corresponding to the second transmitted beamlet group; and
determine a distance between the LiDAR apparatus and at least one object based on at least one of the first set of reflected light signals and the second set of reflected light signals.
